(19) United States
(12) Patent Application Publication
(10) Pub. No.: US 2025/0160077 A1
(43) Pub. Date: May 15, 2025

(54) DISPLAY DEVICE

(71) Applicant: LG Display Co., Ltd., Seoul (KR)

(72) Inventors: Yanghwan KIM, Seoul (KR); HeeJin IM, Goyang-si (KR)

(21) Appl. No.: 18/809,067

(22) Filed: Aug. 19, 2024

(30) Foreign Application Priority Data
Nov. 15, 2023 (KR) 10-2023-0158032

(51) Int. Cl. H01L 33/60; H01L 25/16

(52) U.S. Cl. CPC H10H 20/856; H01L 25/167

(57) ABSTRACT

Provided is a display device. The display device includes a substrate. The display device includes a plurality of patterns disposed on the substrate. The display device includes a reflective plate disposed on the plurality of patterns. The display device includes a light-emitting element disposed on the reflective plate. The plurality of patterns are closed curves.

### CROSS-REFERENCE TO RELATED APPLICATIONS

This application claims the priority of Korean Patent Application No. 10-2023-0158032 filed on Nov. 15, 2024, in the Korean Intellectual Property Office, the disclosure of which is incorporated herein by reference.

### BACKGROUND

### Technical Field

The present disclosure relates to a display device, and more particularly, to a display device which is capable of improving a transfer precision of a plurality of light emitting diodes.

### Description of the Related Art

As display devices which are used for a monitor of a computer, a television, a cellular phone, or the like, there are an organic light emitting display (OLED) device, which is a self-emitting device, a liquid crystal display (LCD) device, which requires a separate light source, and the like.

An applicable range of the display device is diversified to personal digital assistants as well as monitors of computers and televisions and a display device with a large display area and a reduced volume and weight is being studied.

Further, in recent years, a display device including a light emitting diode is attracting attention as a next generation display device. Since the light emitting diode is formed of an inorganic material, rather than an organic material, reliability is excellent so that a lifespan thereof is longer than that of the liquid crystal display device or the organic light emitting display device. Further, the light emitting diode has a fast lighting speed, excellent luminous efficiency, and a strong impact resistance so that a stability is excellent and an image having a high luminance can be displayed.

### BRIEF SUMMARY

Various embodiments of the present specification provide a display device with improved front brightness.

Various embodiments of the present specification provide a display device that reduces a degree to which light, which propagates toward a side surface, is lost by total reflection.

Various embodiments of the present specification provide a high-brightness display device.

Technical benefits of the present disclosure are not limited to the above-mentioned benefits, and other benefits, which are not mentioned above, can be clearly understood by those skilled in the art from the following descriptions.

According to an aspect of the present disclosure, there is provided a display device. The display device comprises a substrate, a plurality of patterns disposed on the substrate, a reflective plate disposed on the plurality of patterns, and a light-emitting element disposed on the reflective plate, wherein the plurality of patterns are closed curves.

According to another aspect of the present disclosure, there is provided a display device. The display device comprises a substrate comprising a light-emitting area and a non-light-emitting area, a reflective plate disposed on the substrate, a light-emitting element disposed on the reflective plate, and a plurality of patterns disposed below the reflective plate, wherein the reflective plate has a concave-convex shape along surfaces of the plurality of patterns, and planar shapes of the plurality of patterns are concentric in shape.

Other detailed matters of the exemplary embodiments are included in the detailed description and the drawings.

According to the present specification, the plurality of patterns is disposed below the light-emitting element, which may improve light extraction efficiency.

According to the present specification, the inclined surfaces are formed on the plurality of patterns, which may improve front brightness.

According to the present specification, the inclination angles of the plurality of patterns are changed depending on the brightness distribution of the light-emitting element, which may minimize a brightness deviation in accordance with a viewing angle.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an embodiment of the present specification;

FIG. 2 is a cross-sectional view of a pixel area of the display device according to the embodiment of the present specification;

FIG. 3 is a top plan view of the pixel area of the display device according to the embodiment of the present specification;

FIG. 4 is a cross-sectional view of a pixel area of a display device according to another embodiment of the present specification;

FIG. 5 is a graph for explaining a brightness distribution of the display device according to another embodiment of the present specification;

FIGS. 6A and 6B are views illustrating propagation paths of light reflected by a reflective plate of the display device in FIG. 4; and

FIG. 7 is a graph for explaining an effect of a display device according to another embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “comprising,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

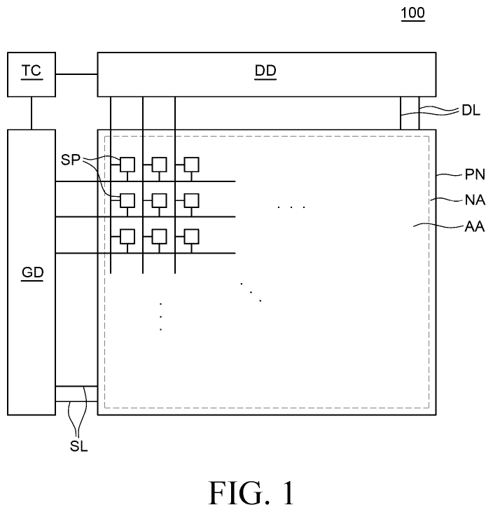

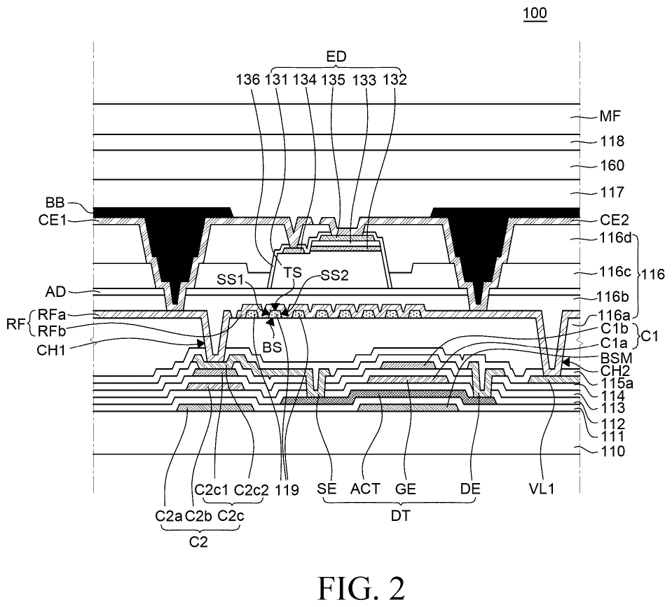

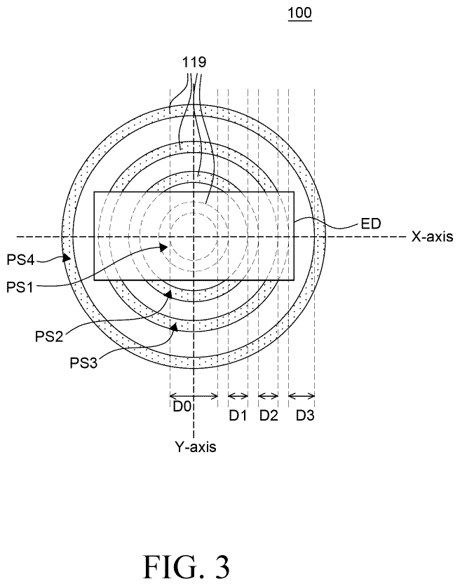

FIG. 1 is a schematic configuration view of a display device according to an embodiment of the present specification. FIG. 2 is a cross-sectional view of a pixel area of the display device according to the embodiment of the present specification. FIG. 3 is a top plan view of the pixel area of the display device according to the embodiment of the present specification. For convenience of description, FIG. 1 illustrates only a display panel PN, a gate drive part GD, a data drive part DD, and a timing controller TC among various constituent elements of a display device 100. For convenience of illustration, FIG. 3 illustrates only a plurality of patterns 119 (also referred to as a plurality of pattern structures 119) and a light-emitting element ED.

With reference to FIG. 1, the display device 100 includes the display panel PN including a plurality of subpixels SP, the gate drive part GD configured to supply various types of signals to the display panel PN, and the timing controller TC configured to control the data drive part DD, the gate drive part GD, and the data drive part DD.

The gate drive part GD supplies a plurality of scan signals to a plurality of scan lines SL in response to a plurality of gate control signals provided from the timing controller TC. FIG. 1 illustrates that the single gate drive part GD is disposed to be spaced apart from one side of the display panel PN. However, the number and arrangement of the gate drive part GD are not limited thereto.

The data drive part DD converts image data, which are inputted from the timing controller TC, into a data voltage by using a reference gamma voltage in response to a plurality of data control signals provided from the timing controller TC. The data drive part DD may supply the converted data voltage to a plurality of data lines DL.

The timing controller TC aligns image data, which are inputted from the outside, and supplies the image data to the data drive part DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and includes the plurality of subpixels SP. In the display panel PN, the plurality of scan lines SL, and the plurality of data lines DL intersect one another, and each of the plurality of subpixels SP is connected to the scan line SL and the data line DL. In addition, although not illustrated in the drawings, the plurality of subpixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include a plurality of subpixels SP constituting a plurality of pixels, and a circuit configured to operate the plurality of subpixels SP. The plurality of subpixels SP is minimum units that constitute the display area AA. The n subpixels SP may constitute a single pixel. A light-emitting element, a thin-film transistor for operating the light-emitting element, and the like may be disposed in each of the plurality of subpixels SP. The plurality of light-emitting elements may be differently defined depending on the type of the display panel PN. For example, in case that the display panel PN is an inorganic light-emitting display panel, the light-emitting element may be a light-emitting diode (LED) or a micro-light-emitting diode (micro-LED).

A plurality of lines for transmitting various types of signals to the plurality of subpixels SP is disposed in the display area AA. For example, the plurality of lines may include the plurality of data lines DL for supplying data voltages to the plurality of subpixels SP, and the plurality of scan lines SL for supplying scan signals to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP. In addition, a low-potential power line, a high-potential power line, and the like may be further disposed in the display area AA. However, the present specification is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate drivers IC and data drivers IC.

Meanwhile, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of subpixels SP by a gate-in-active area (GIA) method in the display area AA. For example, the data drive part DD and the timing controller TC may be formed on a separate flexible film and the printed circuit board PCB. The data drive part DD and the timing controller TC may be electrically connected to the display panel PN by bonding the flexible film and the printed circuit board PCB to the pad electrode formed in the non-display area NA of the display panel PN.

First, with reference to FIG. 2, the display panel PN includes a substrate 110. The substrate 110 may be a substrate, i.e., an insulation substrate configured to support the constituent elements disposed on an upper portion of the display device 100. The plurality of pixels may be formed on the substrate 110 so that images may be displayed. For example, the substrate 110 may be made of glass, resin, or the like. In addition, the substrate 110 may include polymer or plastic. In several embodiments, the substrate 110 may be made of a plastic material having flexibility.

The plurality of subpixels SP may be disposed in a plurality of rows and a plurality of columns on the substrate 110. The plurality of subpixels SP may each include the light-emitting element ED and a pixel circuit and independently emit light.

A plurality of lines for transmitting various types of signals to the plurality of subpixels SP is disposed on the substrate 110. For example, the plurality of data lines DL, a plurality of high-potential power lines VL1, and a plurality of low-potential power lines, which extend in a column direction, may be disposed on the substrate 110. For example, a plurality of light-emitting control signal lines, a plurality of auxiliary high-potential power lines, a plurality of auxiliary low-potential power lines, and a plurality of scan lines, which extend in a row direction, may be disposed on the substrate 110. Further, the high-potential power line VL1, which extends in the column direction, and the auxiliary high-potential power line, which extends in the row direction, may be electrically connected to each other through a contact hole. In this case, the light-emitting control signal lines transmit light-emitting control signals to the pixel circuits of the plurality of subpixels SP to control light-emitting timings of the plurality of subpixels SP. However, the types of the plurality of lines are provided for illustrative purposes only, and the types of the plurality of lines, which may be actually used, may be variously changed in accordance with design.

The pixel circuit for operating the light-emitting element ED is disposed in each of the plurality of subpixels SP on the substrate 110. The pixel circuit may include a plurality of thin-film transistors and a plurality of capacitors. For convenience of description, FIG. 2 illustrates only a driving transistor DT, a first capacitor C1, and a second capacitor C2 among the components of the pixel circuit. However, the pixel circuit may further include a switching transistor, a sensing transistor, a light emission control transistor, and the like. However, the present specification is not limited thereto.

A light-blocking layer BSM, the driving transistor DT, the first capacitor C1, the second capacitor C2, the plurality of patterns 119, a reflective plate RF, the plurality of light-emitting elements ED, a first connection electrode CE1, a second connection electrode CE2, a bank BB, a protective layer 117, an encapsulation layer 160, a bonding part 118, an optical film MF, and insulation layers including a plurality of inorganic insulation layers and a plurality of organic insulation layers may be disposed on the substrate 110.

Among the insulation layers disposed on the substrate 110, the plurality of inorganic insulation layers includes a buffer layer 111, a gate insulation layer 112, a first interlayer insulation layer 113, a second interlayer insulation layer 114, and a first passivation layer 115a.

In addition, among the insulation layers disposed on the substrate 110, the plurality of organic insulation layers may include a first planarization layer 116a, a second planarization layer 116b, a bonding layer AD, a third planarization layer 116c, and a fourth planarization layer 116d.

With reference to FIG. 2, the light-blocking layer BSM is disposed on the substrate 110. The light-blocking layer BSM may block light entering active layers ACT of a plurality of transistors, thereby minimizing a leakage current. For example, the light-blocking layer BSM may be disposed below the active layer ACT of the driving transistor DT and block light entering the active layer ACT. If the light is emitted to the active layer ACT, a leakage current occurs, which may degrade the reliability of the transistor. Therefore, the light-blocking layer BSM for blocking light may be disposed on the substrate 110, thereby improving the reliability of the driving transistor DT. The light-blocking layer BSM may be made of an opaque electrically conductive material, for example, copper (Cu), aluminum (Al), molybdenum (Mo), nickel (Ni), titanium (Ti), chromium (Cr), or an alloy thereof. However, the present specification is not limited thereto.

The buffer layer 111 is disposed on the light-blocking layer BSM. The buffer layer 111 is an inorganic insulation layer capable of reducing the penetration of moisture or impurities through the substrate 110. For example, the buffer layer 111 may be configured as a single layer or multilayer made of silicon oxide (SiOx) or silicon nitride (SiNx). However, the present specification is not limited thereto. However, the buffer layer 111 may be excluded in accordance with the type of substrate 110 or the type of thin-film transistor. However, the present specification is not limited thereto.

The driving transistor DT including the active layer ACT, a gate electrode GE, a source electrode SE, and a drain electrode DE is disposed on the buffer layer 111.

Meanwhile, although not illustrated in FIG. 2, an additional buffer layer may be disposed between the substrate 110 and the light-blocking layer BSM. Like the buffer layer 111, the additional buffer layer may be an inorganic insulation layer capable of reducing the penetration of moisture or impurities through the substrate 110. For example, the additional buffer layer may be configured as a single layer or multilayer made of silicon oxide (SiOx) or silicon nitride (SiNx). However, the present specification is not limited thereto.

First, the active layer ACT of the driving transistor DT is disposed on the buffer layer 111. The active layer ACT may be made of a semiconductor material such as an oxide semiconductor, amorphous silicon, or polysilicon. However, the present specification is not limited thereto. In addition, although not illustrated in the drawings, in addition to the driving transistor DT, other transistors, such as a switching transistor, a sensing transistor, and a light emission control transistor, may be additionally disposed. The active layers of these transistors may be made of a semiconductor material such as an oxide semiconductor, amorphous silicon, or polysilicon. However, the present specification is not limited thereto. In addition, the active layers of the transistors, such as the driving transistor DT, the switching transistor, the sensing transistor, and the light emission control transistor, which are included in the pixel circuits, may be made of the same material or different materials.

The gate insulation layer 112 is disposed on the active layer ACT. The gate insulation layer 112 may be an inorganic insulation layer for electrically insulating the active layer ACT and the gate electrode GE. The gate insulation layer 112 may be configured as a single layer or multilayer made of silicon oxide (SiOx) or silicon nitride (SiNx). However, the present specification is not limited thereto.

The gate electrode GE is disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present specification is not limited thereto.

The first interlayer insulation layer 113 and the second interlayer insulation layer 114 are disposed on the gate electrode GE. Contact holes, through which the source electrode SE and the drain electrode DE are connected to the active layer ACT, are formed in the first interlayer insulation layer 113 and the second interlayer insulation layer 114. The first interlayer insulation layer 113 and the second interlayer insulation layer 114 are inorganic insulation layers for protecting components disposed below the first interlayer insulation layer 113 and the second interlayer insulation layer 114. The first interlayer insulation layer 113 and the second interlayer insulation layer 114 may each be configured as a single layer or multilayer made of silicon oxide (SiOx) or silicon nitride (SiNx). However, the present specification is not limited thereto.

The source electrode SE and the drain electrode DE are disposed on the second interlayer insulation layer 114 and electrically connected to the active layer ACT. The source electrode SE is connected to the second capacitor C2 and a first electrode 134 of the light-emitting element ED, and the drain electrode DE is connected to another component of the pixel circuit. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present specification is not limited thereto.

The plurality of high-potential power lines VL1 is disposed on the second interlayer insulation layer 114. The plurality of high-potential power lines VL1 may transmit high-potential power voltages to the light-emitting elements ED of the plurality of subpixels SP. The plurality of high-potential power lines VL1 may be made of an electrically conductive material, for example, copper (Cu), aluminum (Al), molybdenum (Mo), nickel (Ni), titanium (Ti), chromium (Cr), or an alloy thereof. However, the present specification is not limited thereto.

Next, the first capacitor C1 is disposed on the gate insulation layer 112. The first capacitor C1 includes a first-first capacitor electrode C1a and a first-second capacitor electrode C1b.

First, the first-first capacitor electrode C1a is disposed on the gate insulation layer 112. The first-first capacitor electrode C1a may be integrated with the gate electrode GE of the driving transistor DT.

The first-second capacitor electrode C1b is disposed on the first interlayer insulation layer 113. The first-second capacitor electrode C1b is disposed to overlap the first-first capacitor electrode C1a with the first interlayer insulation layer 113 interposed therebetween.

Therefore, the first capacitor C1 may be connected to the gate electrode GE of the driving transistor DT and maintain the voltage of the gate electrode GE of the driving transistor DT for a predetermined period.

Next, the second capacitor C2 is disposed on the substrate 110. The second capacitor C2 includes a second-first capacitor electrode C2a, a second-second capacitor electrode C2b, and a second-third capacitor electrode C2c. The second capacitor C2 includes the second-first capacitor electrode C2a, which is a lower capacitor electrode, the second-second capacitor electrode C2b, which is an intermediate capacitor electrode, and the second-third capacitor electrode C2c that is an upper capacitor electrode.

The second-first capacitor electrode C2a is disposed on the substrate 110. The second-first capacitor electrode C2a may be disposed on the same layer and made of the same material as the light-blocking layer BSM.

The second-second capacitor electrode C2b is disposed on the buffer layer 111 and the gate insulation layer 112. The second-second capacitor electrode C2b may be disposed on the same layer and made of the same material as the gate electrode GE.

The second-third capacitor electrode C2c is disposed on the first interlayer insulation layer 113. The second-third capacitor electrode C2c may include a first layer C2c1 and a second layer C2c2. The first layer C2c1 of the second-third capacitor electrode C2c may be disposed on the same layer and made of the same material as the first-second capacitor electrode C1b. The first layer C2c1 may be disposed to overlap the second-first capacitor electrode C2a and the second-second capacitor electrode C2b with the first interlayer insulation layer 113 interposed therebetween.

The second layer C2c2 of the second-third capacitor electrode C2c is disposed on the second interlayer insulation layer 114. The second layer C2c2 is a portion extending from the source electrode SE of the driving transistor DT, and the second layer C2c2 may be connected to the first layer C2c1 through the contact hole of the second interlayer insulation layer 114.

Therefore, the second capacitor C2 may be electrically connected between the light-emitting element ED and the source electrode SE of the driving transistor DT and increase the inherent capacitance of the light-emitting element ED, such that the light-emitting element ED may emit light with higher brightness.

The first passivation layer 115a is disposed on the driving transistor DT, the first capacitor C1, and the second capacitor C2. The first passivation layer 115a may be an inorganic insulation layer for protecting components disposed below the first passivation layer 115a. The first passivation layer 115a may be made of an inorganic material such as silicon oxide (SiOx) or silicon nitride (SiNx). However, the present specification is not limited thereto.

The first planarization layer 116a is disposed on the first passivation layer 115a. The first planarization layer 116a may planarize an upper portion of the pixel circuit including the driving transistor DT. The first planarization layer 116a may be configured as a single layer or multilayer. For example, the first planarization layer 116a may be configured as an organic insulation layer made of benzocyclobutene or an acrylic-based organic material.

With reference to FIGS. 2 and 3, the plurality of patterns 119 each having a closed-loop shape may be disposed on the first planarization layer 116a. The plurality of patterns 119 may be concentric in shape, and spacing distances between the plurality of patterns 119 may be equal to one another. However, the present specification is not limited thereto. The plurality of patterns 119 may have various closed-loop shapes, and the spacing distances between the plurality of patterns 119 may be different from one another.

The plurality of patterns 119 may be disposed to overlap the plurality of light-emitting elements ED disposed above the plurality of patterns 119. Meanwhile, the plurality of patterns 119 may be disposed so as not to overlap the bank BB. That is, the plurality of patterns 119 may be disposed to overlap only the light-emitting element ED without overlapping the bank BB disposed to surround the pattern 119, which is disposed at an outermost periphery among the plurality of patterns 119, to suppress a color mixture. However, the present specification is not limited thereto.

With reference to FIG. 2, the plurality of patterns 119 may each have side surfaces that are inclined with respect to a bottom surface of each of the plurality of patterns 119. Therefore, a cross-sectional shape of each of the plurality of patterns 119 may be a trapezoidal shape, for example. However, the present specification is not limited thereto.

With reference to FIG. 2, the plurality of reflective plates RF is disposed on the first planarization layer 116a and the plurality of patterns 119. The reflective plates RF may be disposed to cover top surfaces and the side surfaces of the plurality of patterns 119 and cover a top surface of the first planarization layer 116a in an area in which the plurality of patterns 119 is not disposed. Therefore, a top surface of the reflective plate RF may have a concave-convex shape in accordance with the shape of each of the plurality of patterns 119 and have the concave-convex shape having closed-loop shapes corresponding to the plurality of patterns 119.

In addition, in case that the side surfaces of the plurality of patterns 119 are inclined with respect to the top surface of the first planarization layer 116a, the reflective plate RF may be disposed to be inclined with respect to the top surface of the first planarization layer 116a in the area that overlap the side surfaces of the plurality of patterns 119.

The reflective plate RF may be configured to reflect the light, which is emitted from the plurality of light-emitting elements ED, toward the upper side of the substrate 110 and have a shape corresponding to each of the plurality of subpixels SP. One reflective plate RF may be disposed to cover most of the area of one subpixel SP. The reflective plate RF may also be used as an electrode that may reflect the light emitted from the light-emitting element ED and electrically connect the light-emitting element ED and the pixel circuit. Therefore, the reflective plate RF may include various conductive layers in consideration of light reflection efficiency and resistance. For example, the reflective plate RF may be made by using an opaque conductive layer, which is made of silver (Ag), aluminum (Al), molybdenum (Mo), titanium (Ti), or an alloy thereof, together with a transparent conductive layer made of indium tin oxide (ITO). However, the structure of the reflective plate RF is not limited thereto.

The reflective plates RF may include a plurality of first reflective plates RFa and a plurality of second reflective plates RFb disposed in each of the plurality of subpixels SP.

The plurality of first reflective plates RFa may reflect the light emitted from the light-emitting element ED to the outside of the display device 100. The plurality of first reflective plates RFa may be disposed for each of the driving transistors DT in the plurality of subpixels SP and electrically connected to the second capacitor C2 and the source electrode SE of the driving transistor DT through a first contact hole CH1.

The plurality of second reflective plates RFb may be disposed to overlap the light-emitting element ED. The plurality of second reflective plates RFb may be disposed for each of the driving transistors DT in the plurality of subpixels SP and connected to the high-potential power line VL1 through a second contact hole CH2. Therefore, the plurality of second reflective plates RFb may reflect the light, which is emitted from the light-emitting element ED to the outside of the display device 100 while supplying a high-potential power voltage to the light-emitting element ED. Therefore, the plurality of patterns 119 may be disposed below the plurality of second reflective plates RFb disposed to overlap the plurality of light-emitting elements ED among the reflective plates RF. However, the present specification is not limited thereto.

Meanwhile, all the plurality of light-emitting elements ED may be separately connected to the high-potential power line VL1 without being connected to the reflective plates RF. However, the present specification is not limited thereto.

With reference to FIG. 2, the second planarization layer 116b is disposed on the plurality of reflective plates RF. The second planarization layer 116b may planarize the upper portions of the plurality of patterns 119. The second planarization layer 116b may be configured as a single layer or multilayer. For example, the second planarization layer 116b may be configured as an organic insulation layer made of benzocyclobutene or an acrylic-based organic material. However, the present specification is not limited thereto.

The bonding layer AD is disposed on the second planarization layer 116b. The bonding layer AD may be formed on the front surface of the substrate 110 and fix the light-emitting element ED disposed on the bonding layer AD. The bonding layer AD may be configured as an organic insulation layer. The bonding layer AD may be made of a photocurable bonding material that may be cured by light. For example, the bonding layer AD may be made of an acrylic-based material including a photosensitive agent. However, the present specification is not limited thereto.

The plurality of light-emitting elements ED is disposed on the bonding layer AD in each of the plurality of subpixels SP. The light-emitting elements ED may be elements configured to emit light by the current and include a first light-emitting element configured to emit red light, a second light-emitting element configured to emit green light, and a third light-emitting element configured to emit blue light. A combination of the light-emitting elements ED may implement various colors including white. For example, the light-emitting element ED may be a light-emitting diode (LED) or a micro-LED. However, the present specification is not limited thereto.

The plurality of light-emitting elements ED each includes a first semiconductor layer 131, an active layer 132, a second semiconductor layer 133, the first electrode 134, and a second electrode 135.

The plurality of light-emitting elements ED may have various structures such as lateral, vertical, and flip-chip structures. The lateral light-emitting element includes the first and second electrodes horizontally disposed at two opposite sides of the active layer. The vertical light-emitting element includes the first and seconds electrodes disposed at upper and lower sides of the active layer. The flip-chip light-emitting element is substantially identical in structure to the lateral light-emitting element. The lateral light-emitting element has the first and second electrodes horizontally disposed at the upper side of the active layer, whereas the flip-chip light-emitting element has the first and second electrodes horizontally disposed at the lower side of the active layer. Hereinafter, the description is made on the assumption that the plurality of light-emitting elements ED has the lateral structure. However, the types of the plurality of light-emitting elements ED are not limited thereto.

The first semiconductor layer 131 is disposed on the bonding layer AD, and the second semiconductor layer 133 is disposed on the first semiconductor layer 131. The first semiconductor layer 131 and the second semiconductor layer 133 may each be a layer formed by doping a particular material with n-type and p-type impurities. For example, the first semiconductor layer 131 and the second semiconductor layer 133 may each be a layer formed by doping a material, such as gallium nitride (GaN), indium aluminum phosphide (InAlP), or gallium arsenic (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present specification is not limited thereto.

The active layer 132 is disposed between the first semiconductor layer 131 and the second semiconductor layer 133. The active layer 132 may emit light by receiving positive holes and electrons from the first semiconductor layer 131 and the second semiconductor layer 133. The active layer 132 may be configured as a single layer or a multi-quantum well (MQW) structure. For example, the active layer 132 may be made of indium gallium nitride (InGaN), gallium nitride (GaN), or the like. However, the present specification is not limited thereto.

Meanwhile, a part of the first semiconductor layer 131 may protrude to the outside of the second semiconductor layer 133 and the active layer 132 and be exposed from the second semiconductor layer 133 and the active layer 132.

The first semiconductor layer 131 may have a shape that surrounds the active layer 132 and the second semiconductor layer 133 in a plan view. That is, both the active layer 132 and the second semiconductor layer 133 may be disposed to overlap the first semiconductor layer 131, and only a part of an inner side of the first semiconductor layer 131 may overlap the active layer 132 and the second semiconductor layer 133.

In this case, the second semiconductor layer 133 and the active layer 132, which protrude in shape from the first semiconductor layer 131, may be referred to as mesa part (MESA). Side surfaces of the mesa part, i.e., a side surface of the second semiconductor layer 133 and a side surface of the active layer 132 may be disposed to be inclined with respect to a bottom surface of the first semiconductor layer 131.

The first electrode 134 is disposed on the first semiconductor layer 131. The first electrode 134 is an electrode that electrically connects the driving transistor DT and the first semiconductor layer 131. In this case, the first semiconductor layer 131 may be a semiconductor layer doped with n-type impurities, and the first electrode 134 may be a cathode. The first electrode 134 may be disposed on a top surface of the first semiconductor layer 131 exposed from the active layer 132 and the second semiconductor layer 133. The first electrode 134 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

The second electrode 135 is disposed on the second semiconductor layer 133. The second electrode 135 may be disposed on a top surface of the second semiconductor layer 133. The second electrode 135 is an electrode that electrically connects the high-potential power line VL1 and the second semiconductor layer 133. In this case, the second semiconductor layer 133 may be a semiconductor layer doped with p-type impurities, and the second electrode 135 may be an anode. The second electrode 135 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

Next, an encapsulation film 136 is disposed to surround the first semiconductor layer 131, the active layer 132, the second semiconductor layer 133, the first electrode 134, and the second electrode 135. The encapsulation film 136 may be made of an insulating material and protect the first semiconductor layer 131, the active layer 132, and the second semiconductor layer 133. Further, a contact hole, through which the first electrode 134 and the second electrode 135 are exposed, may be formed in the encapsulation film 136, such that the first connection electrode CE1, the second connection electrode CE2, the first electrode 134, and the second electrode 135 may be electrically connected.

Meanwhile, a part of a side surface of the first semiconductor layer 131 may be exposed from the encapsulation film 136. The light-emitting element ED manufactured on a wafer may be separated from the wafer and transferred to the display panel PN. However, a part of the encapsulation film 136 may be torn during a process of separating the light-emitting element ED from the wafer. For example, a part of the encapsulation film 136 adjacent to a lower edge of the first semiconductor layer 131 of the light-emitting element ED may be torn during the process of separating the light-emitting element ED from the wafer, such that a part of a lower side surface of the first semiconductor layer 131 may be exposed to the outside. However, even though the lower portion of the light-emitting element ED is exposed from the encapsulation film 136, the first connection electrode CE1 and the second connection electrode CE2 are formed after the third and fourth planarization layers 116c and 116d, which cover the side surface of the first semiconductor layer 131, are formed, thereby reducing a short circuit defect.

Next, the third planarization layer 116c and the fourth planarization layer 116d are disposed on the bonding layer AD and the light-emitting element ED.

The third planarization layer 116c may partially overlap the side surfaces of the plurality of light-emitting elements ED and fix and protect the plurality of light-emitting elements ED. The third planarization layer 116c may be configured as a single layer or multilayer. For example, the third planarization layer 116c may be configured as an organic insulation layer made of benzocyclobutene or an acrylic-based organic material. The third planarization layer 116c may be formed by using a halftone mask. Therefore, the third planarization layer 116c may be formed to have a stepped portion.

Specifically, a portion of the third planarization layer 116c, which is relatively adjacent to the light-emitting element ED, may be formed to have a relatively small thickness, and a portion of the third planarization layer 116c, which is relatively distant from the light-emitting element ED, may be formed to have a relatively large thickness. The portion of the third planarization layer 116c, which is adjacent to the light-emitting element ED, may be disposed to surround the light-emitting element ED and adjoin the side surface of the light-emitting element ED. Therefore, the third planarization layer 116c may cover a portion of the encapsulation film 136 configured to protect the side surface of the first semiconductor layer 131 of the light-emitting element ED, which is torn during the process of separating the light-emitting element ED from the wafer and transferring the light-emitting element ED to the display panel PN. Therefore, it is possible to suppress the contact between the first connection electrode CE1, the second connection electrode CE2, and the first semiconductor layer 131 and a short circuit defect later.

The fourth planarization layer 116d may be formed to cover an upper portion of the third planarization layer 116c and an upper portion of the light-emitting element ED. A contact hole, through which the first electrode 134 and the second electrode 135 of the light-emitting element ED are exposed, may be formed in the fourth planarization layer 116d. The first electrode 134 and the second electrode 135 of the light-emitting element ED are exposed from the fourth planarization layer 116d, and the fourth planarization layer 116d may be partially disposed in the area between the first electrode 134 and the second electrode 135, thereby reducing a short circuit defect. The third planarization layer 116c and the fourth planarization layer 116d may each be configured as a single layer or multilayer and made of a photoresist or an acrylic-based organic insulating material, for example.

Meanwhile, the fourth planarization layer 116d may cover the light-emitting element ED and an area adjacent to the light-emitting element ED. The fourth planarization layer 116d may be disposed in an area of the subpixel SP surrounded by the bank BB and disposed in the form of an island. Therefore, the bank BB may be disposed on a part of the top surface of the third planarization layer 116c. For example, the bank BB may be disposed on the fourth planarization layer 116d and overlap a part of the fourth planarization layer 116d.

The first connection electrode CE1 and the second connection electrode CE2 are disposed on the fourth planarization layer 116d.

The first connection electrode CE1 is an electrode that electrically connects the driving transistor DT and the first electrode 134 of the light-emitting element ED. The first connection electrode CE1 may be electrically connected to the first electrode 134, which is exposed from the fourth planarization layer 116d, and simultaneously electrically connected to the first reflective plate RFa through contact holes formed in the fourth planarization layer 116d, the third planarization layer 116c, the bonding layer AD, and the second planarization layer 116b. Therefore, the first electrode 134 and the source electrode SE of the driving transistor DT may be electrically connected through the first connection electrode CE1 and the first reflective plate RFa.

The second connection electrode CE2 is an electrode that electrically connects the high-potential power line VL1 and the second electrode 135 of the light-emitting element ED. The second connection electrode CE2 may be electrically connected to the second electrode 135, which is exposed from the fourth planarization layer 116d, and connected to the second reflective plate RFb through contact holes formed in the fourth planarization layer 116d, the third planarization layer 116c, the bonding layer AD, and the second planarization layer 116b. Therefore, the second electrode 135 and the high-potential power line VL1 may be electrically connected through the second connection electrode CE2.

The first connection electrode CE1 and the second connection electrode CE2 may be made of a transparent conductive material such as indium tin oxide (ITO) or indium zinc oxide (IZO). However, the present specification is not limited thereto.

Meanwhile, the drawings illustrate that the first electrode 134, the first connection electrode CE1, and the first reflective plate RFa are electrically connected to the source electrode SE of the driving transistor DT. However, the first electrode 134, the first connection electrode CE1, and the first reflective plate RFa may be connected to the drain electrode DE of the driving transistor DT. However, the present specification is not limited thereto.

With reference to FIG. 2, the bank BB is disposed on the first connection electrode CE1, the second connection electrode CE2, and the third planarization layer 116c exposed from the fourth planarization layer 116d. The bank BB may be disposed to be spaced apart from the light-emitting element ED at a predetermined interval and at least partially overlap the reflective plate RF. For example, the bank BB may cover a part of the first connection electrode CE1 and a part of the second connection electrode CE2 formed in the contact hole of the fourth planarization layer 116d and the contact hole of the third planarization layer 116c. In addition, for example, the bank BB may be disposed on the third planarization layer 116c and spaced apart from the light-emitting element ED at a predetermined interval.

The bank BB may be made of an opaque material, for example, black resin to reduce a color mixture between the plurality of subpixels SP. However, the present specification is not limited thereto.

Meanwhile, a thickness of a portion of the bank BB, which is formed in the contact hole of the fourth planarization layer 116d and the contact hole of the third planarization layer 116c and covers a part of the first connection electrode CE1 and a part of the second connection electrode CE2, may be different from a thickness of a portion of the bank BB disposed on the third planarization layer 116c. Specifically, in the case of the portion of the bank BB that covers a part of the first connection electrode CE1 and a part of the second connection electrode CE2 formed in the contact hole of the fourth planarization layer 116d and the contact hole of the third planarization layer 116c, the contact hole is formed from the second planarization layer 116b to the fourth planarization layer 116d, such that the bank BB may be disposed to the lower portion of the light-emitting element ED, i.e., a position lower than the light-emitting element ED. Therefore, a thickness of the portion of the bank BB, which covers a part of the first connection electrode CE1 and a part of the second connection electrode CE2 formed in the contact hole of the fourth planarization layer 116d and the contact hole of the third planarization layer 116c, may be larger than a thickness of the portion of the bank BB disposed on the third planarization layer 116c.

Meanwhile, the present specification is not limited thereto. The bank BB may be disposed outside the contact hole of the fourth planarization layer 116d and the contact hole of the third planarization layer 116c and cover a part of the first connection electrode CE1 and a part of the second connection electrode CE2.

The protective layer 117 is disposed on the first connection electrode CE1, the second connection electrode CE2, and the bank BB. The protective layer 117 is a layer for protecting components disposed below the protective layer 117. The protective layer 117 may be configured as a single layer or multilayer. For example, the protective layer 117 may be made of benzocyclobutene, light transmissive epoxy, a photoresist, or an acrylic-based organic material. However, the present specification is not limited thereto.

The encapsulation layer 160 may be disposed above the protective layer 117. The encapsulation layer 160 is a layer for minimizing the penetration of moisture from the outside of the display device 1000 and encapsulating the constituent element surrounded by the encapsulation layer 160. The encapsulation layer 160 may be disposed to surround the front surface, the side surface, and the rear surface of the first substrate 110.

The encapsulation layer 160 may be made of a material with low moisture permeability and high insulating properties. For example, the encapsulation layer 160 may be made of a material including parylene. However, the present specification is not limited thereto.

With reference to FIG. 2, the optical film MF is disposed on the entire area of the upper portion of the substrate 110 and covers an upper portion of the encapsulation layer 160. The optical film MF may be disposed on a seal member 150 and the protective layer 117. The optical film MF may be a functional film that implements images with higher image quality while protecting the display device 100. For example, the optical film MF may include an anti-scattering film, an anti-glare film, an anti-reflecting film, a low-reflecting film, an OLED transmittance controllable film, or a polarizing plate. However, the present disclosure is not limited thereto.

The bonding part 118 may be disposed above the substrate 110 and disposed between the protective layer 117 and the optical film MF. The bonding part 118 may be formed on the front surface of the substrate 110 and bond the protective layer 117 and the optical film MF. The bonding part 118 may be made of a photocurable bonding material that may be cured by light. For example, the bonding part 118 may be made of an acrylic-based material including a photosensitive agent. However, the present specification is not limited thereto.

Meanwhile, in the present specification, the bonding part 118 and the optical film MF are defined as separate constituent elements. However, the present specification is not limited thereto. The optical film MF and the bonding part 118 may be defined as a single constituent element.

Referring to FIGS. 2 and 3, at least one of the plurality of patterns 119 overlap with the light-emitting element ED from a plan view. For example, the plurality of pattern structures 119 includes a first pattern structure PS1, a second pattern structure PS2, a third pattern structure PS3, and a fourth pattern structure PS4. As shown in FIG. 3, While the first pattern structure PS1, the second pattern structure PS2, and the third pattern structure PS3 overlap with the light-emitting element ED from a plan view, the fourth pattern structure PS4 does not overlap with the light-emitting element ED from a plan view. In addition, each pattern structure of the plurality of pattern structures 119 are spaced apart from each other. This is both shown in the plan view of FIG. 3 and the cross-sectional view of FIG. 2.

As shown in FIG. 3, the plurality of pattern structures 119 is concentric with each other from a plan view. In some embodiments, the plurality of pattern structures 119 shares a common axis (e.g., X-axis) and is symmetric with respect to the X-axis. Similarly, the plurality of pattern structures 119 shares a common axis (e.g., Y-axis) and is symmetric with respect to the Y-axis.

The first pattern structure PS1 may have a diameter DO. The first pattern structure PS1 and the second pattern structure PS2 are spaced apart from each other at a first distance D1. The second pattern structure PS2 and the third pattern structure PS3 are spaced apart from each other at a second distance D2. The third pattern structure PS3 and the fourth pattern structure PS4 are spaced apart from each other at a third distance D3. In some embodiments, each pattern structure of the plurality of pattern structures 119 are evenly spaced apart from each other. For example, the first distance D1, the second distance D2, the third distance D3 are identical to each other. However, in other embodiments, each pattern structure of the plurality of pattern structures 119 may be differently spaced apart from each other (e.g., D1≠D2≠D3).

In the display device, a brightness deviation according to a viewing angle occurs in accordance with a shape of the light-emitting element and component tolerance. In case that a micro-light-emitting diode (micro-LED) is used for the light-emitting element, the side brightness may be higher than the front brightness. For example, the brightness may increase in a direction of 50 to 70 degrees, and the maximum brightness may be made in a direction of about 60 degrees. Therefore, a graph of the brightness distribution according to the viewing angle may have an ‘M’ shape, and a Mura phenomenon may occur.

In addition, in the case of the micro-light-emitting diode (micro-LED), the brightness distribution according to the viewing angle may vary depending on an inclination angle of the area, which is called the mesa part of the light-emitting element, i.e., inclination angles of the side surface of the second semiconductor layer and the side surface of the active layer. Meanwhile, because the light-emitting element is manufactured to have a small size, the shape and inclination angle of the mesa part may be affected even by a small tolerance error. For example, in case that the light-emitting element is manufactured to have a size of about 30 μm, a deviation may occur on an inclination angle of the mesa part even by a tolerance at a μm level. Therefore, it may be difficult to control a viewing angle deviation according to a process error.

Therefore, in the display device 100 according to the embodiment of the present specification, the plurality of patterns 119 is disposed below the reflective plate RF, and the side surfaces of the plurality of patterns 119 are formed as inclined surfaces. Therefore, the reflective plate RF may be disposed to have the inclined surface in the area that overlaps the side surfaces of the plurality of patterns 119, and the light emitted from the light-emitting element ED may be reflected by the inclined surface of the reflective plate RF and extracted in the direction of the front surface. Therefore, in the display device 100 according to the embodiment of the present specification, the plurality of patterns 119 disposed below the reflective plate RF may reduce the amount of light propagating in the direction of the side surface and extract the light in the direction of the front surface. Therefore, the front brightness of the display device 100 may increase, and the viewing angle deviation may be reduced.

In addition, in the display device 100 according to the embodiment of the present specification, the plurality of patterns 119 having closed curve shapes is disposed below the reflective plate RF, and all the plurality of patterns 119 may have the same center. Therefore, the reflective plate RF disposed on the plurality of patterns 119 may include a plurality of concave-convex patterns having centers identical to the centers of the plurality of patterns 119. Therefore, the light emitted from the light-emitting element ED may be reflected by the reflective plate RF disposed on the plurality of patterns 119 and propagate toward the centers of the plurality of patterns 119. Therefore, in case that the reflective plate RF includes the plurality of concave-convex patterns having the same center, the light extracted from the light-emitting element ED may be concentrated in the direction of the front surface in comparison with the case in which the reflective plate RF has a concave-convex pattern having an open shape. Therefore, in the display device 100 according to the embodiment of the present specification, the front brightness of the display device 100 may increase, such that a high-efficiency, high-brightness display device 100 may be provided.

Referring to FIG. 3, each pattern structure of the plurality of pattern structures PS1, PS2, PS3, PS4 may have a polygonal shape, a circular shape, a ring shape, a donut shape, or the like from a plan view.

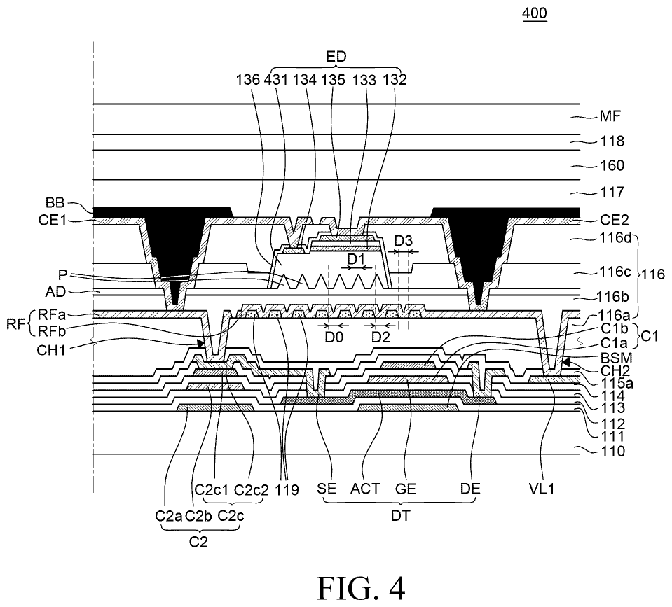

FIG. 4 is a cross-sectional view of a pixel area of a display device according to another embodiment of the present specification. A display device 400 illustrated in FIG. 4 is substantially identical in configuration to the display device 100 illustrated in FIGS. 1 to 3, except for the light-emitting element ED. Therefore, a repeated description of the identical components will be omitted.

With reference to FIG. 4, the display device 400 in FIG. 4 includes the light-emitting element ED disposed on the bonding layer AD.

The light-emitting element ED may include a plurality of light extraction patterns P. The plurality of light extraction patterns may be disposed to be inclined with respect to the substrate 110 and disposed on a bottom surface of the light-emitting element ED. In this case, the plurality of light extraction patterns P may be inclined with respect to the substrate 110. For example, as illustrated in FIG. 4, a cross-sectional shape of each of the plurality of light extraction patterns P may be a triangular shape. However, the present specification is not limited thereto.

Meanwhile, the bonding layer AD may fill the plurality of light extraction patterns P. In case that the light-emitting element ED is joined onto the bonding layer AD, the plurality of light extraction patterns P may be filled with the bonding layer AD by an external force. Meanwhile, the bonding layer AD may fill all or only some of the plurality of light extraction patterns P. However, the present specification is not limited thereto.

In some embodiments, the plurality of light extraction patterns P overlaps with the light-emitting element ED from a plan view. In some embodiments, the plurality of light extraction patterns P, the reflective plate RF, the plurality of patterns 119, and the light-emitting element ED at least partially overlap with each other from a plan view.

Meanwhile, as the number of light extraction patterns P for the same area increases, the efficiency of the light-emitting element ED may increase. Therefore, the light extraction pattern P may be disposed to have a high inclination angle to increase the number of light extraction patterns P disposed on the bottom surface of the light-emitting element ED. For example, the plurality of light extraction patterns P may be disposed to be inclined with respect to the substrate 110 at 70° to 80°. However, the present specification is not limited thereto.

Meanwhile, in case that the inclination angle of the light extraction pattern P with respect to the substrate 110 is 70 to 80 degrees, the inclination angle of the inclined surface of each of the plurality of patterns 119 with respect to the substrate 110 may be 25° to 40°.

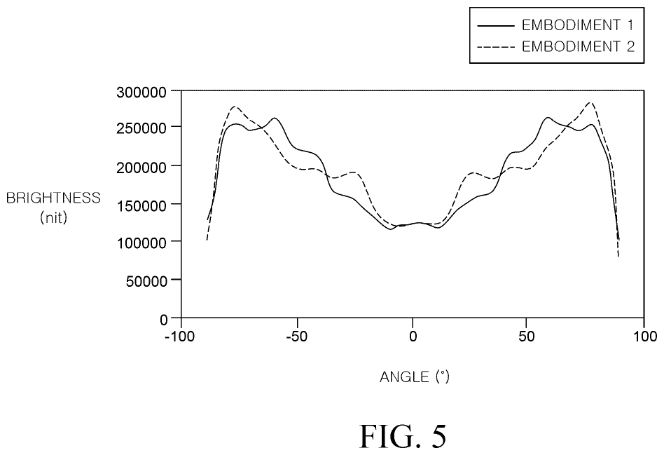

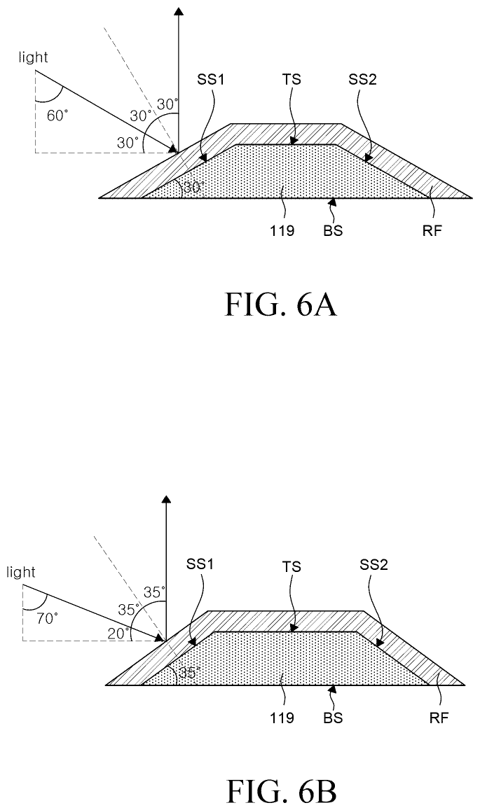

Hereinafter, the inclined surfaces of the plurality of patterns 119 and the inclination angle of the light extraction pattern P will be described with reference to FIGS. 5 to 6B.

FIG. 5 is a graph for explaining a brightness distribution of the display device 400 in FIG. 4 of the present specification.

FIG. 5 is a graph showing brightness distributions according to viewing angles measured in Embodiments 1 and 2. Embodiments 1 and 2 in FIG. 5 show the brightness distributions of the light propagating toward the lower portion of the light-emitting element ED in the display device 400 in FIG. 4. The X-axis in the graph in FIG. 5 indicates angles (°), and a central portion of the light-emitting element ED is set to 0°. The Y-axis in the graph in FIG. 5 indicates brightness (nit), i.e., the brightness of the light beams propagating in the direction of the side surface among the light beams propagating to the lower portion of the light-emitting element ED. Embodiment 1 is a case in which the inclination angle of the plurality of light extraction patterns P is 70°, and Embodiment 2 is a case in which the inclination angle of the plurality of light extraction patterns P is 80°.

With reference to FIG. 5, in Embodiments 1 and 2, the brightness of the side surface of the light-emitting element ED is higher than the brightness of the central portion of the light-emitting element ED. Specifically, the maximum brightness is made at an angle of about 60° in Embodiment 1, and the maximum brightness is made at an angle of about 70° in Embodiment 2.

Hereinafter, the description will be made with reference to FIGS. 6A and 6B together.

FIGS. 6A and 6B are views illustrating propagation paths of light reflected by the reflective plate RF of the display device 400 in FIG. 4. FIGS. 6A and 6B are views illustrating propagation paths of the light reflected by the area of the reflective plate RF that overlap the inclined surfaces of the plurality of patterns 119. FIG. 6A is a view illustrating a propagation path of the light in case that an angle of the inclined surface (e.g., a first side surface SS1, a second side surface SS2) of the plurality of patterns 119 is 30°. FIG. 6B is a view illustrating a propagation path of the light in case that an angle of the inclined surface (e.g., a first side surface SS1, a second side surface SS2) of the plurality of patterns 119 is 35°. Here, a pattern structure has a top surface TS, a bottom surface BS opposite the top surface TS, a first side surface SS1 facing a second side surface SS2 (also referred to an inclined surface). As illustrated in FIGS. 6A and 6B, in some embodiments, the reflective plate RF covers and directly contacts the first side surface SS1, the second side surface SS2, and the top surface TS of each pattern structure of the plurality of patterns 119.

FIG. 6A illustrates the light beams propagating at an angle of 60° among the light beams propagating in the direction of the side surface (e.g., a first side surface SS1, a second side surface SS2). The light propagating at an angle of 60° is reflected by the area that overlaps the inclined surfaces of the plurality of patterns 119. In this case, as illustrated in FIG. 6A, in case that the light propagating at an angle of 60° is reflected by the inclined surfaces of the plurality of patterns 119 having an inclination angle of 30°, the reflected light may propagate in the direction of the front surface.

Therefore, the light beams, which propagate at an angle of 60° among the light beams propagating toward the lower portion of the light-emitting element ED, may be reflected by the inclined surfaces of the plurality of patterns 119 having an inclination angle of 30° and propagate in the direction of the front surface. As in Embodiment 1 in FIG. 5, in case that the light propagating toward the lower portion of the light-emitting element ED has the maximum brightness at an angle of about 60°, the plurality of patterns 119 having an inclination angle of 30° may be disposed to reduce the brightness deviation according to the viewing angle.

FIG. 6B illustrates the light beams propagating at an angle of 70° among the light beams propagating in the direction of the side surface. The light propagating at an angle of 70° is reflected by the area that overlaps the inclined surfaces (e.g., a first side surface SS1, a second side surface SS2) of the plurality of patterns 119. In this case, as illustrated in FIG. 6B, in case that the light propagating at an angle of 70° is reflected by the inclined surfaces (e.g., a first side surface SS1, a second side surface SS2) of the plurality of patterns 119 having an inclination angle of 35°, the reflected light may propagate in the direction of the front surface.

Therefore, the light beams, which propagate at an angle of 70° among the light beams propagating toward the lower portion of the light-emitting element ED, may be reflected by the inclined surfaces of the plurality of patterns 119 having an inclination angle of 35° and propagate in the direction of the front surface. As in Embodiment 2 in FIG. 5, in case that the light propagating toward the lower portion of the light-emitting element ED has the maximum brightness at an angle of about 70°, the plurality of patterns 119 having an inclination angle of 35° may be disposed to reduce the brightness deviation according to the viewing angle.

Therefore, in case that the light propagating toward the lower portion of the light-emitting element ED has the maximum brightness at an angle of about 60° to 70°, the plurality of patterns 119 having an inclination angle of about 30° to 40° may be disposed to reduce the brightness deviation. Meanwhile, the inclination angle of the inclined surface (e.g., a first side surface SS1, a second side surface SS2) of the plurality of patterns 119 may be designed to be 25° to 40° in consideration of a process margin. Namely, in some embodiments, an inclination angle defined between the bottom surface BS and the first side surface SS1 is about 25° to 40°. However, the present specification is not limited thereto.

Referring to FIGS. 2 and 6, according to some embodiments, the bottom surface BS of each pattern structure of the plurality of patterns 119 is on and directly contacts the planarization layer 116a. The reflective plate RFa, RFb directly contacts the planarization layer 116a.

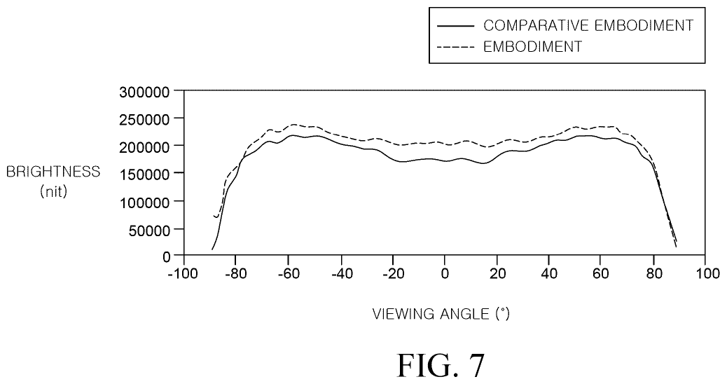

FIG. 7 is a graph for explaining an effect of a display device according to another embodiment of the present specification. Embodiment in FIG. 7 is the display device 400 according to another embodiment of the present specification. Comparative embodiment in FIG. 7 differs from the display device 400 according to another embodiment of the present specification only in that the plurality of patterns 119 is not disposed, and the reflective plate RF is disposed along a flat top surface of the first planarization layer 116a.

FIG. 7 illustrates brightness distributions according to viewing angles measured in Comparative embodiment and Embodiment. The X-axis in the graph in FIG. 7 indicates viewing angles (°). The Y-axis in the graph in FIG. 7 indicates brightness (nit).

With reference to FIG. 7, in Comparative embodiment and Embodiment, the brightness of the side surface at 50° to 70° is higher than the brightness of the front surface, and the maximum brightness is made in the direction of the side surface at about 60°.

Specifically, in the direction of the side surface at about 60°, Comparative embodiment shows the maximum brightness of about 220,000 nits, and Embodiment shows the maximum brightness of about 240,000 nits. Therefore, it can be ascertained that the maximum brightness in Embodiment is higher than the maximum brightness in Comparative embodiment.

With reference to FIG. 7, Comparative embodiment shows the front brightness of about 170,000 nits, and Embodiment shows the front brightness of about 200,000 nits. Therefore, it can be ascertained that the front brightness is improved in Embodiment in which the plurality of patterns 119 is disposed in comparison with Comparative embodiment in which the plurality of patterns 119 is not disposed.

Therefore, in the display device 400 according to another embodiment of the present specification, the plurality of patterns 119 having the inclined surfaces is disposed below the reflective plate RF, such that the front brightness of the display device 400 may be improved, and the viewing angle deviation may be reduced.

In addition, in the display device 400 according to another embodiment of the present specification, the plurality of patterns 119 having the closed curve shapes having the same center is disposed below the reflective plate RF, such that the front brightness of the display device 400 may be increased, and the high-efficiency, high-brightness display device 400 may be provided.

In addition, in the display device 400 according to another embodiment of the present specification, the plurality of light extraction patterns P is disposed on the light-emitting element ED, such that the light extraction efficiency of the display device 400 may be improved.

In addition, in the display device 400 according to another embodiment of the present specification, the inclination angle of the plurality of patterns 119 may be adjusted to correspond to the maximum brightness of the light-emitting element ED. For example, the light propagating toward the lower portion of the light-emitting element ED has the maximum brightness at an angle of about 60° to 70°, the plurality of patterns 119 having an inclination angle of about 30° to 40° is disposed below the light-emitting element ED. Therefore, the light propagating at an angle of about 60° to 70° may be reflected by the inclined surfaces of the plurality of patterns 119 having an inclination angle of about 30° to 40° and propagate in the direction of the front surface. Therefore, in the display device 400 according to another embodiment of the present specification, the propagation direction of the light having the maximum brightness is reflected in the direction of the front surface, such that the front brightness of the display device 400 may be improved, and the viewing angle deviation may be reduced.

The exemplary embodiments of the present disclosure can also be described as follows:

According to an aspect of the present disclosure, there is provided a display device. The display device comprises a substrate, a plurality of patterns disposed on the substrate, a reflective plate disposed on the plurality of patterns, and a light-emitting element disposed on the reflective plate, wherein the plurality of patterns are closed curves.

A top surface of the reflective plate may have a concave-convex shape along shapes of the plurality of patterns.

The plurality of patterns may be disposed to overlap the light-emitting element.

The plurality of patterns may have trapezoidal shapes having inclined surfaces.

The reflective plate may cover top surfaces and side surfaces of the plurality of patterns.

The display device may further comprise a bank disposed in an outer peripheral area of the light-emitting element, wherein the plurality of patterns may be disposed so as not to overlap the bank.

The light-emitting element may comprise a plurality of light extraction patterns disposed on a bottom surface of the light-emitting element and inclined with respect to the substrate, and wherein an inclination angle of the plurality of light extraction patterns with respect to the substrate may be 70° to 80°.

The plurality of patterns may be disposed to overlap the light-emitting element, and wherein an inclination angle of side surfaces of the plurality of patterns with respect to the substrate may be 25° to 40°.

The display device may further comprise a first planarization layer disposed between the substrate and the plurality of patterns, a second planarization layer configured to planarize upper portions of the plurality of patterns on the reflective plate, and a bonding layer disposed on the second planarization layer, wherein the light-emitting element may be disposed on the bonding layer.

According to another aspect of the present disclosure, there is provided a display device. The display device comprises a substrate comprising a light-emitting area and a non-light-emitting area, a reflective plate disposed on the substrate, a light-emitting element disposed on the reflective plate, and a plurality of patterns disposed below the reflective plate, wherein the reflective plate has a concave-convex shape along surfaces of the plurality of patterns, and planar shapes of the plurality of patterns are concentric in shape.

The display device may further comprise a bank disposed on the light-emitting element and configured to surround the light-emitting element, wherein the bank may be disposed to surround the pattern disposed at an outermost periphery among the plurality of patterns.

The display device may further comprise a planarization layer disposed below the plurality of patterns, wherein the reflective plate may cover a part of a top surface of the planarization layer and top surfaces of the plurality of patterns.

Side surfaces of the plurality of patterns may be inclined with respect to the top surface of the planarization layer.

The reflective plate may be disposed to be inclined with respect to the top surface of the planarization layer in an area that overlaps the side surfaces of the plurality of patterns.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a plurality of patterns on the substrate;
a reflective plate on the plurality of patterns; and
a light-emitting element on the reflective plate,
wherein the plurality of patterns are closed curves.

2. The display device of claim 1, wherein a top surface of the reflective plate has a concave-convex shape along shapes of the plurality of patterns.

3. The display device of claim 1, wherein the plurality of patterns is disposed to overlap the light-emitting element from a plan view.

4. The display device of claim 1, wherein the plurality of patterns has trapezoidal shapes having inclined surfaces.

5. The display device of claim 4, wherein the reflective plate covers top surfaces and side surfaces of the plurality of patterns.

6. The display device of claim 1, further comprising:
a bank in an outer peripheral area of the light-emitting element,
wherein the plurality of patterns is disposed so as not to overlap the bank from a plan view.

7. The display device of claim 1, wherein the light-emitting element comprises a plurality of light extraction patterns on a bottom surface of the light-emitting element and inclined with respect to the substrate, and
wherein an inclination angle of the plurality of light extraction patterns with respect to the substrate is 70° to 80°.

8. The display device of claim 7, wherein the plurality of patterns is disposed to overlap the light-emitting element from a plan view, and
wherein an inclination angle of side surfaces of the plurality of patterns with respect to the substrate is 25° to 40°.

9. The display device of claim 1, further comprising:
a first planarization layer disposed between the substrate and the plurality of patterns;
a second planarization layer configured to planarize upper portions of the plurality of patterns on the reflective plate; and
a bonding layer on the second planarization layer,
wherein the light-emitting element is disposed on the bonding layer.

10. A display device, comprising:
a substrate having a light-emitting area and a non-light-emitting area;
a reflective plate on the substrate;
a light-emitting element on the reflective plate; and
a plurality of patterns disposed below the reflective plate,
wherein the reflective plate has a concave-convex shape along surfaces of the plurality of patterns, and planar shapes of the plurality of patterns are concentric in shape.

11. The display device of claim 10, further comprising:
a bank on the light-emitting element and configured to surround the light-emitting element,
wherein the bank is disposed to surround a pattern disposed at an outermost periphery among the plurality of patterns.

12. The display device of claim 10, further comprising:
a planarization layer disposed below the plurality of patterns,
wherein the reflective plate covers a part of a top surface of the planarization layer and top surfaces of the plurality of patterns.

13. The display device of claim 12, wherein side surfaces of the plurality of patterns are inclined with respect to the top surface of the planarization layer.

14. The display device of claim 13, wherein the reflective plate is disposed to be inclined with respect to the top surface of the planarization layer in an area that overlaps the side surfaces of the plurality of patterns.

15. The display device of claim 10, wherein the light-emitting element comprises a plurality of light extraction patterns on a bottom surface of the light-emitting element and inclined with respect to the substrate, and
wherein an inclination angle of the plurality of light extraction patterns with respect to the substrate is 70° to 80°.

16. The display device of claim 15, wherein the plurality of patterns are disposed to overlap the light-emitting element, and
wherein an inclination angle of side surfaces of the plurality of patterns with respect to the substrate is 25° to 40°.

17. A display device, comprising:
a thin film transistor on a substrate;
a light-emitting element electrically connected to the thin film transistor;
a plurality of pattern structures between the thin film transistor and the light-emitting element,
wherein at least one of the plurality of pattern structures overlap with the light-emitting element from a plan view, and
wherein each pattern structure of the plurality of pattern structures is spaced apart from each other.

18. The display device of claim 17, wherein each pattern structure of the plurality of pattern structures is evenly spaced apart from each other.

19. The display device of claim 17, wherein each pattern structure of the plurality of pattern structures has either a circular shape or a ring shape from a plan view.

20. The display device of claim 17, wherein the plurality of pattern structures is concentric with each other from a plan view.

21. The display device of claim 17, wherein the plurality of pattern structures shares a common axis and are symmetric with respect to the common axis.

22. The display device of claim 17, wherein each pattern structure of the plurality of pattern structures has a top surface, a bottom surface opposite the top surface, a first side surface facing a second side surface, and
wherein an inclination angle defined between the bottom surface and the first side surface is about 25° to 40°.

23. The display device of claim 17, further comprising:
a reflective plate on the plurality of pattern structures,
wherein each pattern structure of the plurality of pattern structures has a top surface, a bottom surface opposite the top surface, a first side surface facing a second side surface, and
wherein the reflective plate covers the first side surface, the second side surface, and the top surface of each pattern structure of the plurality of pattern structures.

24. The display device of claim 23, further comprising:
a planarization layer on the thin film transistor;
wherein the bottom surface of each pattern structure of the plurality of pattern structures is on and directly contacts the planarization layer, and
wherein the reflective plate directly contacts the planarization layer.

25. The display device of claim 17, further comprising:
a plurality of light extraction patterns on the reflective plate,
wherein the plurality of light extraction patterns overlaps with the light-emitting element from a plan view.

26. The display device of claim 25, wherein the plurality of light extraction patterns, the reflective plate, the plurality of pattern structures, and the light-emitting element at least partially overlap with each other from a plan view.
